(19) United States
(12) Patent Application Publication
(10) Pub. No.: US 2005/0009342 A1
(43) Pub. Date: Jan. 13, 2005

(54) Method for etching an organic anti-reflective coating (OARC)

(75) Inventors: Hui Chen, Milpitas, CA (US); Chun Yan, San Jose, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(73) Assignee: Applied Materials, Inc.

(21) Appl. No.: 10/616,098

(22) Filed: Jul. 8, 2003

(51) Int. Cl. H01L 21/302; H01L 21/461

(52) U.S. Cl. 438/689

(57) ABSTRACT

A method for etching an organic anti-reflective coating (OARC) using a halogen-free gas chemistry is disclosed. The organic anti-reflective coating (OARC) is etched using a gas mixture comprising at least one of a hydrocarbon-containing gas and an oxygen-containing gas. The method provides high etch selectivity for the organic anti-reflective coating (OARC) over metal layers (e.g., copper (Cu), aluminum (Al), and the like) or dielectric layers (silicon dioxide (SiO₂), and the like).

### BACKGROUND OF THE INVENTION

1. Field of the Invention

The present invention generally relates to a method of fabricating devices on semiconductor substrates. More specifically, the invention relates to a method for etching an organic anti-reflective coating (OARC).

2. Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities necessitate reduced dimensions for the integrated circuit components (e.g., sub-micron dimensions).

As the dimensions of the integrated circuit components are reduced, process equipment employing deep ultraviolet (DUV) imaging wavelengths (e.g., wavelengths less than about 250 nm (nanometers)) is generally used. The DUV imaging wavelengths improve resist pattern resolution because diffraction effects are reduced at these shorter wavelengths. However, the increased reflective nature of many underlying materials (e.g., polysilicon, copper (Cu), aluminum (Al)) at such DUV wavelengths can degrade the dimensions of resulting resist patterns.

One technique proposed to minimize reflections from an underlying material layer uses an organic anti-reflective coating (OARC) (e.g., carbon-containing polymeric material). The OARC is formed over the reflective material layer prior to resist patterning. The OARC suppresses the reflections off the underlying material layer during resist imaging, providing accurate pattern replication in the layer of resist.

After the layer of resist is patterned, such pattern is typically transferred through the OARC layer using a plasma etch process. The OARC etch processes generally use halogen-containing gas chemistries (e.g., fluorine (F) and chlorine (Cl)). These halogen-containing gas chemistries typically have a low etch selectivity for the underlying material layer (e.g., polysilicon, copper (Cu), aluminum (Al)) and may undesirably contaminate or erode such underlying material layer.

Therefore, what is needed in the art is a method for etching an organic anti-reflective coating (OARC).

### SUMMARY OF THE INVENTION

The present invention is a method for etching an organic anti-reflective coating (OARC) using a halogen-free gas chemistry. The organic anti-reflective coating (OARC) is etched using a gas mixture comprising at least one of a hydrocarbon-containing gas and an oxygen-containing gas. The method provides high etch selectivity for the organic anti-reflective coating (OARC) over metal layers (e.g., copper (Cu), aluminum (Al), and the like) or dielectric layers (silicon dioxide (SiO₂), and the like).

### BRIEF DESCRIPTION OF THE DRAWINGS

The teachings of the present invention can be readily understood by considering the following detailed description in conjunction with the accompanying drawings, in which:

FIG. 1 depicts a flow diagram of a method for etching an organic anti-reflective coating (OARC) in accordance with an embodiment of the present invention;

FIGS. 2A-2D depict a sequence of schematic, cross-sectional views of a substrate having an organic anti-reflective coating being etched in accordance with the method of FIG. 1;

FIG. 3 depicts a schematic diagram of an exemplary plasma processing apparatus of the kind used in performing portions of the inventive method; and

FIG. 4 is a table summarizing the processing parameters of one exemplary embodiment of the inventive method when practiced using the apparatus of FIG. 3.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method for etching an organic anti-reflective coating (OARC) using a halogen-free gas chemistry. The organic anti-reflective coating (OARC) is etched using a gas mixture comprising at least one of a hydrocarbon-containing gas and an oxygen-containing gas. The method provides high etch selectivity for the organic anti-reflective coating (OARC) over metal layers (e.g., copper (Cu), aluminum (Al), and the like) or dielectric layers (silicon dioxide (SiO₂), and the like).

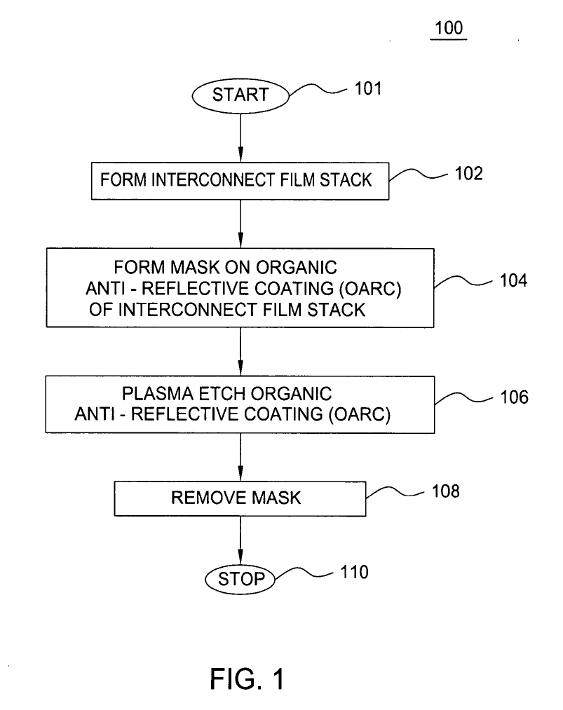

FIG. 1 depicts a flow diagram of one embodiment of the inventive method for etching an organic anti-reflective coating (OARC) as sequence 100. The sequence 100 includes the processes that are performed upon a film stack during fabrication of an interconnect structure.

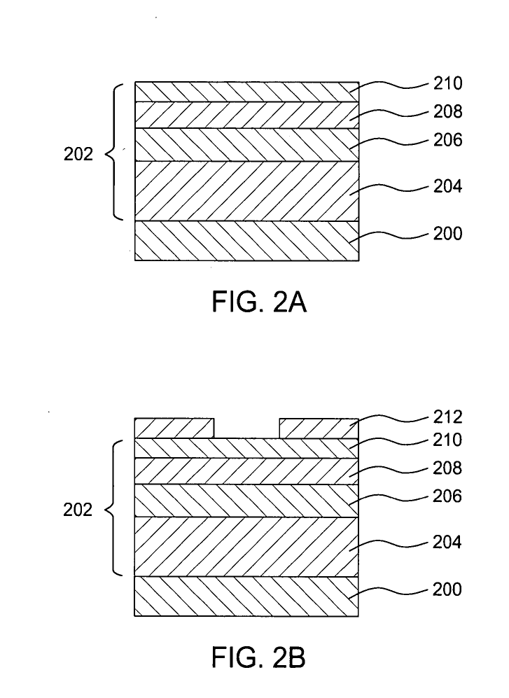

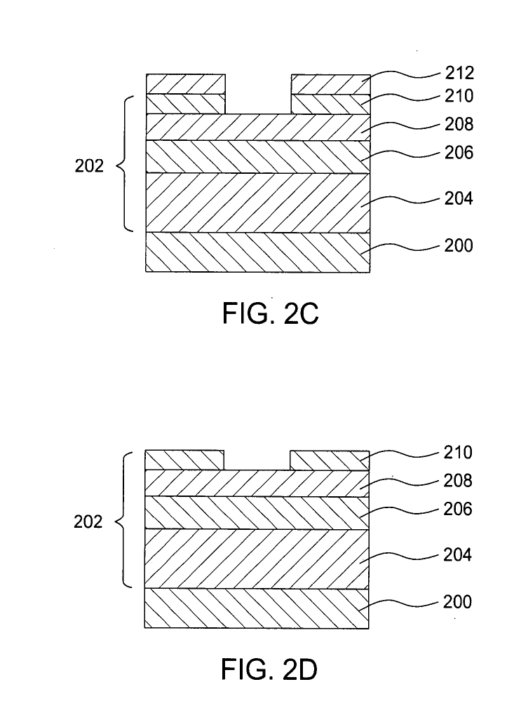

FIGS. 2A-2D depict a series of schematic, cross-sectional views of a substrate comprising an interconnect structure being formed using the sequence 100. To best understand the invention, the reader should simultaneously refer to FIGS. 1 and 2A-2D. The cross-sectional views in FIGS. 2A-2D relate to the process steps that are used to form the interconnect structure. Sub-processes and lithographic routines (e.g., exposure and development of photoresist, wafer cleaning procedures, and the like) are well known in the art and, as such, are not shown in FIG. 1 and FIGS. 2A-2D. The images in FIGS. 2A-2D are not depicted to scale and are simplified for illustrative purposes.

The sequence 100 starts at step 101 and proceeds to step 102, when an interconnect structure film stack 202 is formed on a substrate 200, such as a silicon (Si) wafer and the like (FIG. 2A). In one embodiment, the interconnect structure film stack 202 comprises a layer of insulating material 204, a barrier layer 206, a layer of conductive material 208, and an organic anti-reflective coating (OARC) 210.

The insulating material layer 204 is generally formed of a dielectric material, such as silicon dioxide (SiO₂), silicon nitride (Si₃N₄), and the like to a thickness of about 1000 to about 5000 Angstroms. The barrier layer 206 is generally formed of titanium (Ti), tungsten (W), tungsten nitride (WN), titanium nitride (TiN), and the like to a thickness of about 100 to about 500 Angstroms. The conductive material layer 208 is formed of aluminum (Al), doped polysilicon (poly Si), copper (Cu), and the like to a thickness of about 1000 to about 5000 Angstroms. The organic anti-reflective coating (OARC) 210 comprises a carbon-containing material, such as polyamide, polysulfone, AZ BARLi® (available from AZ Electronic Materials, Somerville, N.J.), and the like, to a thickness of about 600 to about 1500 Angstroms. It is to be understood that, in other embodiments, the interconnect structure film stack 202 may comprise layers that are formed from different materials.

The layers of the interconnect film stack 202 can be formed using any conventional thin film deposition technique, such as atomic layer deposition (ALD), physical vapor deposition (PVD), chemical vapor deposition (CVD), plasma enhanced CVD, spin coating, and the like. Fabrication of the interconnect structures may be performed using the respective processing reactors of CENTURA®, ENDURA®, and other semiconductor wafer processing systems available from Applied Materials, Inc. of Santa Clara, Calif.

At step 104, a mask 212 is formed on top of the organic anti-reflective coating (OARC) 210 (FIG. 2B). The mask 212 defines location and topographic dimensions for interconnect structures being fabricated. In the depicted embodiment, the mask protects regions 220 of the interconnect structure film stack 202 and exposes region 222 thereof. In one exemplary embodiment, the mask 212 is a patterned photoresist mask.

At step 106, the organic anti-reflective coating (OARC) 210 is plasma etched using a gas mixture comprising at least one of a hydrocarbon-containing gas and an oxygen-containing gas (FIG. 2C). During step 106, the organic anti-reflective coating (OARC) 210 is removed in the unprotected region 222. The hydrocarbon-containing gas has a formula CₓH_{y}, where x and y are integers. The hydrocarbon-containing gas may comprise for example, ethylene (C₂H₄), methane (CH₄), ethylyne (C₂H₂), ethane (C₂H₆), and the like. The oxygen-containing gas may comprise for example carbon dioxide (CO₂), oxygen (O₂), carbon monoxide (CO), sulfur dioxide (SO₂), and the like. The gas mixture may optionally include one or more inert gases such as, at least one of nitrogen (N₂), helium (He), argon, (Ar), neon (Ne), and the like. The gas mixture comprising at least one of the hydrocarbon-containing gas and the oxygen-containing gas facilitates an etch selectivity for the organic anti-reflective coating (OARC) (layer 210) over the conductive material (layer 208) of about 20:1. In one embodiment, step 106 uses the photoresist mask 212 as an etch mask and the conductive layer 208 as an etch stop layer.

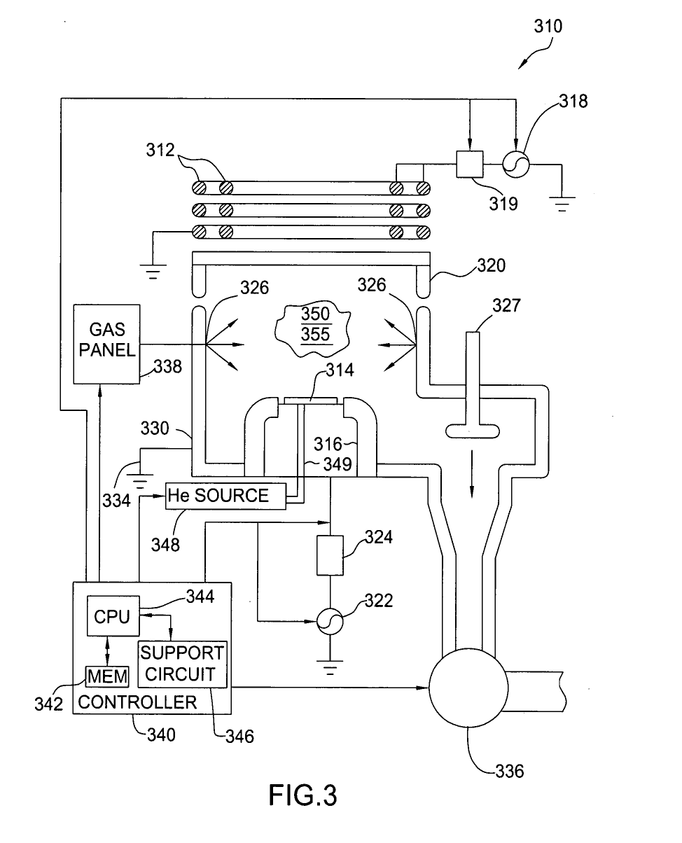

Step 106 can be performed in an etch reactor such as a Decoupled Plasma Source (DPS) II module of the CENTURA® system. The DPS II module (described in detail in reference to FIG. 3 below) uses a 2 MHz inductive source to produce a high-density plasma.

In one illustrative embodiment, an organic anti-reflective coating (ORAC) layer 210 comprising polyamide is etched in the DPS II module by providing ethylene (C₂H₄) up to 3% by volume diluted with helium (He) at a flow rate of about 30 sccm to about 200 sccm, nitrogen (N₂) at a flow rate of about 10 sccm to about 600 sccm (i.e., a C₂H₄/He:N₂ flow ratio ranging from 20:1 to 3:1), applying power to the inductively coupled antenna between 500 to 1200 W, applying a cathode bias power between 50 to 200 W, and maintaining a wafer temperature of about 10 to 60 degrees Celsius at a pressure in the process chamber of between 1 to 30 mTorr. The nitrogen (N₂) may optionally be replaced with oxygen (O₂), carbon dioxide (CO₂), and the like such that the gas chemistry comprises for example, C₂H₄He/O₂, C₂H₄He/CO₂, as well as their mixtures C₂H₄He/N₂/O₂, and C₂H₄He/N₂/CO₂.

One illustrative process provides ethylene (C₂H₄) 2.7% by volume diluted with helium (He) at a flow rate of 50 sccm, nitrogen (N₂) at a flow rate of 5 sccm (i.e., a C₂H₄/He:N₂ flow ratio of 10:1), applies 600 W of power to the antenna, applies 100 W of bias power and maintains a wafer temperature of 40 degrees Celsius at a pressure of 2 mTorr. Such a process provides etch selectivity for ORAC (layer 210) over titanium nitride (TiN) (layer 208) of at least 20:1.

In an alternate embodiment, the organic anti-reflective coating (OARC) layer 210 comprising polyamide is etched in the DPS II module by providing carbon dioxide (CO₂) at a flow rate of about 20 sccm to about 100 sccm, nitrogen (N₂) at a flow rate of about 20 sccm to about 100 sccm (i.e., a CO₂:N₂ flow ratio ranging from 5:1 to 1:5), applying power to the inductively coupled antenna between 500 to 1200 W, applying a cathode bias power between 50 to 200 W, and maintaining a wafer temperature of about 10 to 60 degrees Celsius at a pressure in the process chamber of between 1 to 10 mTorr.

One illustrative process provides carbon dioxide (CO₂) at a flow rate of 50 sccm, nitrogen (N₂) at a flow rate of 10 sccm (i.e., a CO₂:N₂ flow ratio of 5:1), applies 500 W of power to the antenna, applies 100 W of bias power and maintains a wafer temperature of 40 degrees Celsius at a chamber pressure of 2 mTorr. Such a process provides etch selectivity for the organic anti-reflective coating (OARC) (layer 210) over silicon dioxide (S₁O₂) (layer 208) of at least 30:1.

At step 108, the mask 212 is optionally removed (or stripped) (FIG. 2D). In one illustrative embodiment, the mask 212 comprising photoresist is stripped in the DPS II module by providing oxygen (O₂) at a flow rate of 10 to 100 sccm, nitrogen (N₂) at a flow rate of 10 to 100 sccm (i.e., a O₂:N₂ flow ratio ranging from 1:10 to 10:1), applying power to the inductively coupled antenna of about 1000 W, applying a cathode bias power of about 10 W, and maintaining a wafer temperature of about 40 degrees Celsius at a pressure in the process chamber of about 32 mTorr. For such an embodiment, the duration of the stripping process is between 30 and 120 seconds.

At step 110, the sequence 100 ends. Subsequent to the completion of sequence 100, further deposition and or etch processes may be performed on the wafer 200 dependant upon the particular device being fabricated.

One illustrative embodiment of an etch reactor that can be used to perform the steps of the present invention is depicted in FIG. 3. FIG. 3 depicts a schematic diagram of the exemplary Decoupled Plasma Source (DPS) II etch reactor 300 that may be used to practice portions of the invention. The DPS II reactor is available from Applied Materials, Inc. of Santa Clara, Calif.

The reactor 300 comprises a process chamber 310 having a wafer support pedestal 316 within a conductive body (wall) 330, and a controller 340.

The chamber 310 is supplied with a substantially flat dielectric ceiling 320. Other modifications of the chamber 310 may have other types of ceilings, e.g., a dome-shaped ceiling. Above the ceiling 320 is disposed an antenna comprising at least one inductive coil element 312 (two co-axial elements 312 are shown). The inductive coil element 312 is coupled, through a first matching network 319, to a plasma power source 318. The plasma power source 318 typically is capable of producing up to 3000 W at a tunable frequency in a range from 50 kHz and 13.56 MHz.

The support pedestal (cathode) 316 is coupled, through a second matching network 324, to a biasing power source 322. The biasing power source 322 generally is capable of producing up to 500 W at a frequency of approximately 13.56 MHz. The biasing power may be either continuous or pulsed power. In other embodiments, the biasing power source 322 may be a DC or pulsed DC source.

The controller 340 comprises a central processing unit (CPU) 344, a memory 342, and support circuits 346 for the CPU 344 and facilitates control of the components of the DPS II etch chamber 310 and, as such, of the etch process, as discussed below in further detail.

In operation, a semiconductor wafer 314 is placed on the pedestal 316 and process gases are supplied from a gas panel 338 through entry ports 326 to form a gaseous mixture 350. The gaseous mixture 350 is ignited into a plasma 355 in the chamber 310 by applying power from the plasma and bias sources 318, 322 to the inductive coil element 312 and the cathode 316, respectively. The pressure within the interior of the chamber 310 is controlled using a throttle valve 327 and a vacuum pump 336. Typically, the chamber wall 330 is coupled to an electrical ground 334. The temperature of the wall 330 is controlled using liquid-containing conduits (not shown) that run through the wall 330.

The temperature of the wafer 314 is controlled by stabilizing the temperature of the support pedestal 316. In one embodiment, helium gas from a gas source 348 is provided via a gas conduit 349 to channels (not shown) formed in the pedestal surface under the wafer 314. The helium gas is used to facilitate heat transfer between the pedestal 316 and the wafer 314. During processing, the pedestal 316 may be heated by a resistive heater (not shown) within the pedestal to a steady state temperature and then the helium gas facilitates uniform heating of the wafer 314. Using such thermal control, the wafer 314 is maintained at a temperature of between 0 and 500 degrees Celsius.

Those skilled in the art will understand that other etch chambers may be used to practice the invention, including chambers with remote plasma sources, electron cyclotron resonance (ECR) plasma chambers, and the like.

To facilitate control of the process chamber 310 as described above, the controller 340 may be one of any form of general-purpose computer processor that can be used in an industrial setting for controlling various chambers and sub-processors. The memory 342, or computer-readable medium, of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The inventive method is generally stored in the memory 342 as a software routine. The software routine may also be stored and/or executed by a second CPU (not shown) that is remotely located from the hardware being controlled by the CPU 344.

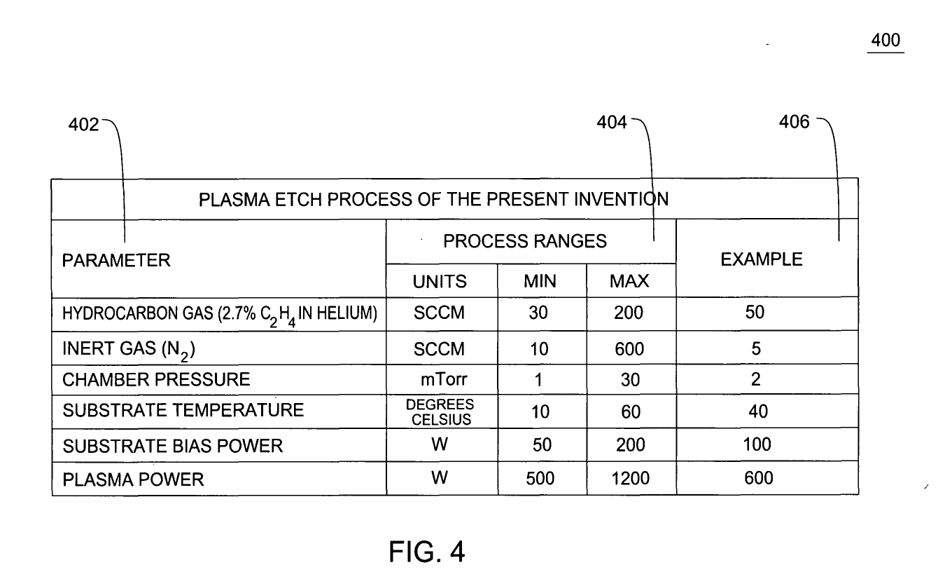

FIG. 4 is a table 400 summarizing the process parameters of the etch process described herein using the DPS II reactor. The process parameters summarized in column 402 are for one exemplary embodiment of the invention presented above. The process ranges are presented in column 404. Exemplary process parameters for etching the organic anti-reflective coating (OARC) 210 are presented in column 406. It should be understood, however, that the use of a different plasma etch reactor may necessitate different process parameter values and ranges.

Although the foregoing discussion referred to fabrication of an interconnect structure, fabrication of other devices and structures that are used in integrated circuits can benefit from the invention including, for example, aluminum etch applications, tungsten etch applications, dielectric and low-K etch applications, dual-damascene applications as well as dual hard-mask dual-damascene applications, among others.

The invention may be practiced using other semiconductor wafer processing systems wherein the processing parameters may be adjusted to achieve acceptable characteristics by those skilled in the art by utilizing the teachings disclosed herein without departing from the spirit of the invention.

While the foregoing is directed to the illustrative embodiment of the present invention, other and further embodiments of the invention may be devised without departing from the basic scope thereof, and the scope thereof is determined by the claims that follow.

1. A method for etching an organic anti-reflective coating (OARC), comprising:
(a) providing a substrate having an organic anti-reflective coating (OARC) thereon;
(b) forming a patterned mask on the organic anti-reflective coating (OARC); and
(c) etching the organic anti-reflective coating (OARC) using a gas mixture comprising at least one of a hydrocarbon-containing gas and an oxygen-containing gas.

2. The method of claim 1 wherein the oxygen-containing gas is selected from the group consisting of oxygen (O₂), carbon dioxide (CO₂), carbon monoxide (CO) and sulfur dioxide (SO₂).

3. The method of claim 1 wherein the hydrocarbon-containing gas has a formula CₓH_{y} where x and y are integers.

4. The method of claim 1 wherein the hydrocarbon-containing gas is selected from the group consisting of methane (CH₄), ethylene (C₂H₄), ethane (C₂H₆) and ethylyne (C₂H₂).

5. The method of claim 1 wherein the organic anti-reflective coating (OARC) comprises a material selected from the group consisting of polyamide and polysulfone.

6. The method of claim 1 wherein the gas mixture further comprises an inert gas.

7. The method of claim 6 wherein the inert gas comprises one or more gases selected from the group consisting of nitrogen (N₂), argon (Ar), helium (He) and neon (Ne).

8. The method of claim 6 wherein the gas mixture comprises the hydrocarbon-containing gas and the inert gas at a hydrocarbon-containing gas:inert gas flow ratio within a range of about 30:1 to about 3:1.

9. The method of claim 6 wherein the gas mixture comprises the oxygen-containing gas and the inert gas at an oxygen-containing gas:inert gas flow ratio within a range of about 5:1 to about 1:5.

10. The method of claim 6 wherein step (c) further comprises:
providing the hydrocarbon-containing gas and the inert gas at a hydrocarbon-containing gas:inert gas flow ratio of about 20:1 to 3:1;
maintaining the substrate at a temperature of about 10 to about 60 degrees Celsius;
applying a plasma power of about 500 W to about 1200 W;
applying a substrate bias power of about 50 W to about 200 W; and
maintaining a process chamber pressure within a range of about 1 mTorr to about 30 mTorr.

11. The method of claim 6 wherein step (c) further comprises:
providing the oxygen-containing gas and the inert gas at an oxygen-containing gas:inert gas flow ratio of about 5:1 to 1:5;
maintaining the substrate at a temperature of about 10 to about 60 degrees Celsius;
applying a plasma power of about 500 W to about 1200 W;
applying a substrate bias power of about 50 W to about 200 W; and
maintaining a process chamber pressure within a range of about 1 mTorr to about 10 mTorr.

12. A method of fabricating an integrated circuit, comprising:
(a) providing a substrate having an organic anti-reflective coating (OARC) formed on one of a metallic layer and a dielectric layer;
(b) forming a patterned mask on the organic anti-reflective coating (OARC); and
(c) etching the organic anti-reflective coating (OARC) using a gas mixture comprising at least one of a hydrocarbon-containing gas and an oxygen-containing gas.

13. The method of claim 12 wherein the oxygen-containing gas is selected from the group consisting of oxygen (O₂), carbon dioxide (CO₂), carbon monoxide (CO) and sulfur dioxide (SO₂).

14. The method of claim 12 wherein the hydrocarbon-containing gas has a formula CₓH_{y} where x and y are integers.

15. The method of claim 12 wherein the hydrocarbon-containing gas is selected from the group consisting of methane (CH₄), ethylene (C₂H₄), ethane (C₂H₆) and ethylyne (C₂H₂).

16. The method of claim 12 wherein the organic anti-reflective coating (OARC) comprises a material selected from the group consisting of polyamide and polysulfone.

17. The method of claim 12 wherein the gas mixture further comprises an inert gas.

18. The method of claim 17 wherein the inert gas comprises one or more gases selected from the group consisting of nitrogen (N₂), argon (Ar), helium (He) and neon (Ne).

19. The method of claim 17 wherein the gas mixture comprises the hydrocarbon-containing gas and the inert gas at a hydrocarbon-containing gas:inert gas flow ratio within a range of about 20:1 to about 3:1.

20. The method of claim 17 wherein the gas mixture comprises the oxygen-containing gas and the inert gas at an oxygen-containing gas:inert gas flow ratio within a range of about 5:1 to about 1:5.

21. The method of claim 12 wherein step (c) provides an etch selectivity for the organic anti-reflective coating (OARC) over the metallic layer of about 20:1.

22. The method of claim 12 wherein step (c) provides an etch selectivity for the organic anti-reflective coating (OARC) over the dielectric layer of about 30:1.

23. The method of claim 17 wherein step (c) further comprises:
providing the hydrocarbon-containing gas and the inert gas at a hydrocarbon-containing gas:inert gas flow ratio of about 20:1 to 3:1;
maintaining the substrate at a temperature of about 10 to about 60 degrees Celsius;
applying a plasma power of about 500 W to about 1200 W;
applying a substrate bias power of about 50 W to about 200 W; and
maintaining a process chamber pressure within a range of about 1 mTorr to about 30 mTorr.

24. The method of claim 17 wherein step (c) further comprises:
providing the oxygen-containing gas and the inert gas at an oxygen-containing gas:inert gas flow ratio of about 5:1 to 1:5;
maintaining the substrate at a temperature of about 10 to about 60 degrees Celsius;
applying a plasma power of about 500 W to about 1200 W;
applying a substrate bias power of about 50 W to about 200 W; and
maintaining a process chamber pressure within a range of about 1 mTorr to about 10 mTorr.

25. A computer-readable medium containing software that when executed by a computer causes a semiconductor wafer processing system to etch an organic anti-reflective coating (OARC) using a method, comprising:
(a) providing a substrate having an organic anti-reflective coating (OARC) thereon;
(b) forming a patterned mask on the organic anti-reflective coating (OARC); and
(c) etching the organic anti-reflective coating (OARC) using a gas mixture comprising at least one of a hydrocarbon-containing gas and an oxygen-containing gas.

26. The computer-readable medium of claim 25 wherein the oxygen-containing gas is selected from the group consisting of oxygen (O₂), carbon dioxide (CO₂), carbon monoxide (CO) and sulfur dioxide (SO₂).

27. The computer-readable medium of claim 25 wherein the hydrocarbon-containing gas has a formula CₓH_{y} where x and y are integers.

28. The computer-readable medium of claim 25 wherein the hydrocarbon-containing gas is selected from the group consisting of methane (CH₄), ethylene (C₂H₄), ethane (C₂H₆) and ethylene (C₂H₂).

29. The computer-readable medium of claim 25 wherein the organic anti-reflective coating (OARC) comprises a material selected from the group consisting of polyamide and polysulfone.

27. The computer-readable medium of claim 23 wherein the gas mixture further comprises an inert gas.

28. The computer-readable medium of claim 27 wherein the inert gas comprises one or more gases selected from the group consisting of nitrogen (N₂), argon (Ar), helium (He) and neon (Ne).
